(19) United States
(12) Patent Application Publication
(10) Pub. No.: US 2008/0029775 A1
(43) Pub. Date: Feb. 7, 2008

(54) Light emitting diode package with positioning groove

(75) Inventors: Chia-Chi Liu, His Chih City (TW); Pao-Chi Chi, His Chih City (TW); Yueh-Hisin Chang, His Chih City (TW)

Correspondence Address: BRUCE H. TROXELL, SUITE 1404, 5205 LEESBURG PIKE, FALLS CHURCH, VA, 22041, US

(73) Assignee: Lustrous Technology Ltd.

(21) Appl. No.: 11/497,412

(22) Filed: Aug. 2, 2006

(51) Int. Cl. H01L 29/227

(52) U.S. Cl. 257/98

(57) ABSTRACT

A light emitting diode package structure includes a light emitting diode, a substrate structure and at least one gel. A surface of the substrate structure has a concave and at least one groove. The concave is used for containing the light emitting diode. A predetermined distance (D) is between the groove and the light emitting diode. The groove is formed around the light emitting diode. The gel covers the light emitting diode and a portion of the surface of the substrate structure. The gel is limited to surface tension in the groove and is positioned in a predetermined region surrounded by the groove.

### BACKGROUND OF THE INVENTION

(1) Field of the Invention

The present invention generally relates to a light emitting diode package structure, and particularly to a light emitting diode package structure having a groove to improve the positioning of the gel.

(2) Description of the Prior Art

The energy that light emitting diodes (LED) need is much less than the energy that the conventional incandescent lights or fluorescent lights need. Therefore, light emitting diodes are applied to many kinds of electronic products and industries more and more commonly. Also, light emitting diodes are very small and light. Thus, light emitting diodes are much better than conventional light sources. With the trend of electronic products becoming lighter and smaller, the demand of light emitting diodes is increasing day by day.

Please refer to FIG. 1A. FIG. 1A is a sectional side view of a conventional light emitting diode package structure 10. The conventional light emitting diode package structure 10 mainly includes a light emitting diode 11, a substrate structure 13, electrodes 15a and 15b, wires 17a and 17b, and a gel 19. The light emitting diode 11 is the main light emitting component in the diode package structure 10. The substrate structure 13 has a concave 13a, so that the light emitting diode 11 can be disposed in the concave 13a. The light emitting diode 11 is electrically connected to the electrodes 15a and 15b by the wires 17a and 17b respectively. The gel 19 is transparent, for covering the light emitting diode 11, the concave 13a, a portion of a surface of the substrate structure 13, and a portion of the wires 17a and 17b. The main objective of the gel 19 is to avoid the invasion of outer particles or moisture. Furthermore, when the diode package structure 10 is disposed in an electronic apparatus, the light emitting diode 11 is driven to light by electrically connecting the electrodes 15a and 15b with a circuit.

Please refer to FIG. 1B. FIG. 1B is a sectional side view of another conventional light emitting diode package structure 20. The diode package structure 20 includes a light emitting diode 21, a substrate structure 23, electrodes 25a and 25b, an electrically conductive layer 27, and a gel 29. The light emitting diode 21 is the main light emitting component in the diode package structure 20. The substrate structure 23 has a concave 23a. The electrically conductive layer 27 can be formed on a surface of the substrate structure 23 by steps such as metal deposition, exposure, and development. The light emitting diode 21 is disposed in the concave 23a and electrically connected to the electrodes 25a and 25b through the electrically conductive layer 27. The gel 29 is transparent, for covering the light emitting diode 21, the concave 23a, a portion of the surface of the substrate structure 23, and a portion of the electrically conductive layer 27. The objective of the gel 29 and the driving method of the light emitting diode 21 are mentioned above and not described redundantly.

FIG. 1A is a so-called wire-bonding type, and FIG. 2 is a so-called flip-chip type. Take FIG. 2 for example. In order to generate light with different colors in the light emitting diode package structure 20, different fluorescent materials are doped in the gel 29. The gel 29 with different fluorescent materials cooperates with the light generated by the light emitting diode 21 to generate light with different colors. For example, blue light generated by a blue light diode cooperating with the gel doped with yellow fluorescent materials presents a white light source.

When dispensed on the light emitting diode 21 by the process of gel dispensing, the gel 29 tends to overflow. As a result, it is difficult to position the gel 29 on the light emitting diode 21 precisely. Therefore, when the light emitting diode 21 emits light, yellow circular light occurs around the gel 29, further effecting the light emitting quality of the light emitting diode package structure 20. The above-described “precisely positioning” means that the gel 29 not only covers the light emitting diode 21 but also is uniformly distributed around the light emitting diode 21.

Moreover, as to the fluorescent materials, it is difficult to distribute the fluorescent materials uniformly in the gel 29. Therefore, when the light generated by the light emitting diode 21 emits to the portion of the gel 29 with more fluorescent materials, more light reflects back to the light emitting diode 21. As a result, some light is wasted. Furthermore, because the distribution of the fluorescent materials in the gel 29 is not uniform, the light generated by the light emitting diode package structure 20 is not uniform.

Therefore, it is important for the industries of the light emitting diode package structure to position the gel 29 precisely on the light emitting diode 21. Accordingly, the occurrence of the yellow circular light is decrease, and the light quality of the light emitting diode package structure 20 is improved. Additionally, the fluorescent materials are distributed uniformly in the gel 29, for reducing the loss of light and generating a uniform light source.

### SUMMARY OF THE INVENTION

An objective of the present invention is to provide a light emitting diode package structure with a groove. When the gel is dispensed, the overflow problem is improved. And the positioning of the gel is improved as well.

Another objective of the present invention is to control forming curvature of the gel.

Another objective of the present invention is to enable the light emitting diode to generate uniform light and to decrease the loss of light.

Another objective of the present invention is to increase the yield of the light emitting diode with several layers of gels.

The present invention provides a light emitting diode package structure including a light emitting diode, a substrate structure and at least one gel. A surface of the substrate structure has a concave and at least one groove. The concave is used for containing the light emitting diode. A predetermined distance is between the groove and light emitting diode. The groove is disposed around the light emitting diode. The gel covers the light emitting diode and a portion of the surface of the substrate structure. The gel is limited to surface tension in the groove and is positioned in a predetermined region surrounded by the groove.

These and other objectives of the present invention will no doubt become obvious to those of ordinary skill in the art after reading the following detailed description of the preferred embodiment which is illustrated in the various figures and drawings.

### BRIEF DESCRIPTION OF THE DRAWINGS

The present invention will now be specified with reference to its preferred embodiment illustrated in the drawings, in which

FIG. 1A is a sectional side view of a conventional light emitting diode package structure;

FIG. 1B is a sectional side view of another conventional light emitting diode package structure;

FIG. 2A is a sectional side view of a light emitting diode package structure according to the first embodiment of the present invention;

FIG. 2B is a top view of the light emitting diode package structure in the FIG. 2A;

FIG. 2C shows different types of grooves in a partial region shown in FIG. 2A;

FIG. 2D illustrates the gel shown in FIG. 2B disposed on different types of the grooves;

FIG. 3A is a sectional side view of a light emitting diode package structure according to the second embodiment of the present invention;

FIG. 3B is a sectional side view of a light emitting diode package structure according to the third embodiment of the present invention;

FIG. 3C is a sectional side view of a light emitting diode package structure according to the fourth embodiment of the present invention;

FIG. 3D is a sectional side view of a light emitting diode package structure according to the fourth embodiment of the invention; and

FIG. 4 is a flow chart of a manufacturing method of a light emitting diode package structure according to the present invention.

### DESCRIPTION OF THE PREFERRED EMBODIMENT

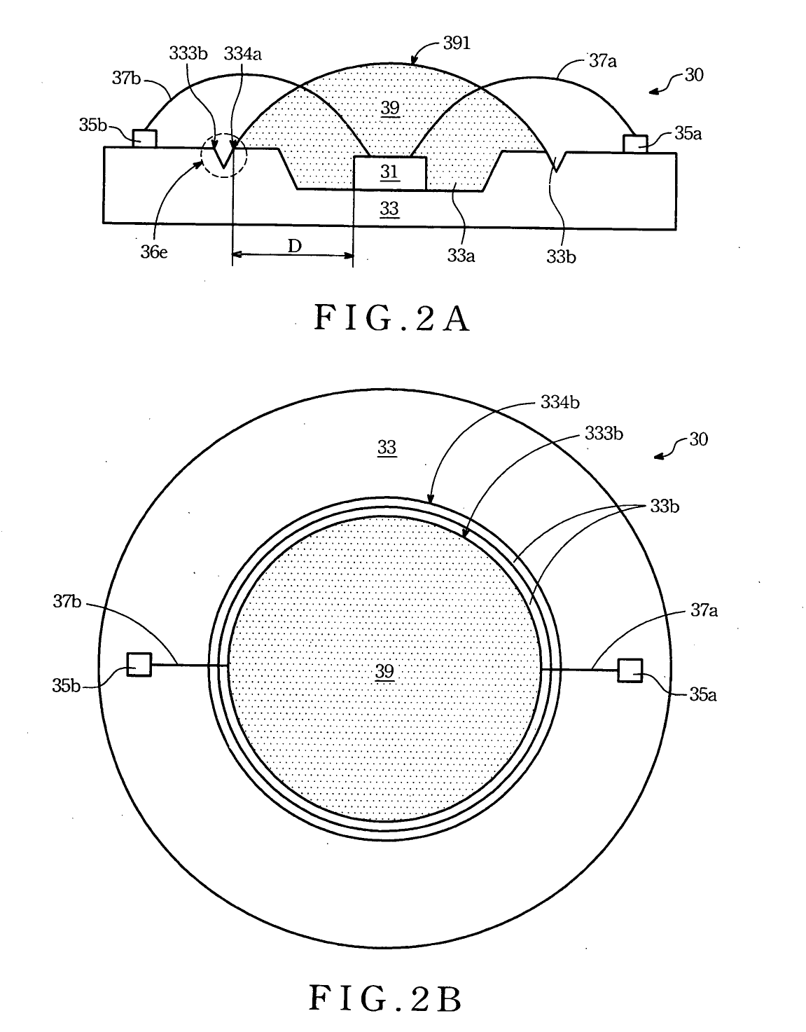

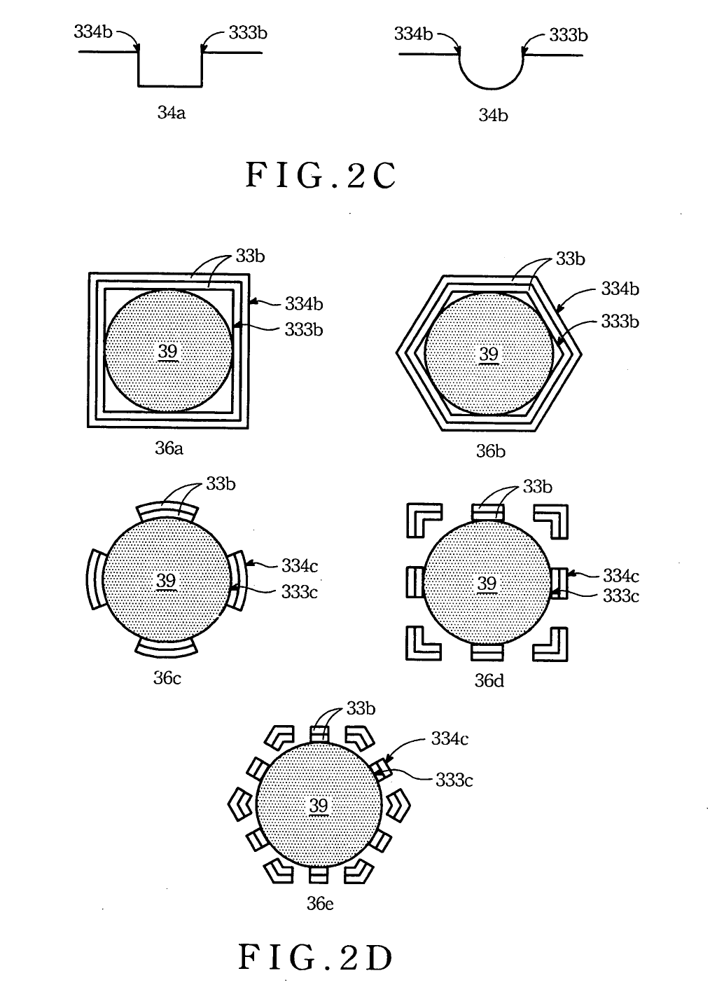

Please refer to FIG. 2A. FIG. 2A is a sectional side view of a light emitting diode package structure 30 according to the first embodiment of the present invention. The light emitting diode package structure 30 includes a light emitting diode 31, a substrate structure 33, electrodes 35a and 35b, wires 37a and 37b, and at least one gel 39. The light emitting diode 31 is the main light emitting component in the light emitting diode package structure 30. The light emitting diode 31 can be a chip. A surface of the substrate structure 33 has a concave 33a and at least one groove 33b. The concave 33a is used for containing the light emitting diode 31. In the present embodiment of the invention, a sectional side view of the groove 33b is a V-shape. The light emitting diode 31 is electrically connected to the electrodes 35a and 35b through the wires 37a and 37b respectively. The gel 39 is transparent, for covering the light emitting diode 31, a portion of the surface of the substrate structure 33, and a portion of the wires 37a and 37b. The portion of the surface of the substrate structure 33 which is covered by the gel 39 includes the concave 33a. The gel 39 can contain fluorescent materials, for cooperating with the light generated by the light emitting diode 31 to generate light with a specific color. The main objective of the gel 39 is to avoid the invasion of outer particles or moisture. Additionally, when the diode package structure 30 is disposed in an electronic apparatus, the electrodes 35a and 35b are electrically connected to a circuit to drive the light emitting diode 31. As a result, the light emitting diode 31 emits light.

The groove 33b is disposed outside the concave 33a. A predetermined distance (D) is between the groove 33b and the light emitting diode 31. The groove 33b is disposed around the light emitting diode 31. The predetermined distance (D) is further described later. In the process of gel dispensing, when the gel 39 is dispensed on the light emitting diode 31, a portion of the surface of the substrate structure 33 and a portion of the wires 37a and 37b, the gel 39 is limited to the surface tension in the discontinuous section of the groove 33b. As a result, the gel 39 is positioned in a predetermined region surrounded by the groove 33b. The predetermined region is further described later.

Please further refer to FIG. 2B. FIG. 2B is a top view of the light emitting diode package structure 30 in the FIG. 2A. The top view of the groove 33b is a circle. Two continuous loop lines 333b and 334b are formed by the groove 33b on the surface of the substrate structure 33. The continuous loop line 333b is closer to the light emitting diode 31 than the continuous loop line 334b. The gel 39 is limited to the surface tension in the discontinuous section of the groove 33b. As a result, the gel 39 is positioned inside the continuous loop line 333b.

Please refer to FIG. 2C. FIG. 2C shows different types of grooves in a partial region 36e shown in FIG. 2A. The sectional side view of the groove 33b can be a V-shape as shown in FIG. 2A. Or, the sectional side view of the groove 33b can also be a rectangle 34a or a semicircle 34b as shown in FIG. 2C.

Please further refer to FIG. 2D. FIG. 2D illustrates the gel 39 shown in FIG. 2B disposed on different types of the grooves. Besides the circle shown in FIG. 2B, the top view of the groove 33b can also be a rectangle 36a, a polygon 36b, a discontinuous circle 36c, a discontinuous rectangle 36d, or a discontinuous polygon 36e as shown in FIG. 2D. The rectangle 36a and the polygon 36b have continuous loop lines 333b and 334b. The continuous circle 36c, the discontinuous rectangle 36d, and the discontinuous polygon 36e have discontinuous loop lines 333c and 334c. The gel 39 is limited to the surface tension in the discontinuous section of the groove 33b. As a result, the gel 39 is positioned inside the continuous loop line 333b or the discontinuous loop line 333c surrounded by the groove 33b. What is worth mentioning is that the gel 39 does not need to completely cover the region inside the continuous loop line 333b or the discontinuous loop line 333c. The gel 39 only need to cover a portion of the region inside the continuous loop line 333b or the discontinuous loop line 333c, as long as the gel 39 is limited to the surface tension in the discontinuous section of the groove 33b and then is positioned inside the continuous loop line 333b or the discontinuous loop line 333c. Moreover, the predetermined region mentioned above is the region surrounded by the continuous loop line 333b or the discontinuous loop line 333c.

What is worth mentioning is that the present invention does not focus on the shape of the sectional view or the shape of the top view of the groove 33b. The point is to form at least one groove 33b on the substrate structure 33. Therefore, in the process of dispensing gel, the gel 39 is limited to the surface tension in the discontinuous section of the groove 33b and then is positioned inside the region surrounded by the groove 33b. All the groove 33b mentioned above can be formed by dry etching.

Therefore, the design of the groove 33b in the present invention enables the gel 39 to be positioned inside the region surrounded by the groove 33b because the gel 39 is limited to the surface tension in the discontinuous section. The overflow problem in the process of gel dispensing is avoided, and the positioning of the gel 39 is improved.

Please refer back to FIG. 2A. The predetermined distance (D) between the groove 33b and the light emitting diode 31 is further illustrated. The predetermined distance (D) is mainly used for controlling the forming curvature (please refer to a gel surface 391 in FIG. 2A) of the gel 39. In other words, when the distance (D) between the groove 33b and the light emitting diode 31 is longer, the forming curvature of the gel 39 becomes less. When the distance (D) between the groove 33b and the light emitting diode 31 is shorter, the forming curvature of the gel 39 becomes greater. Therefore, when the gel is dispensed, the forming curvature of the gel 39 is controlled by adjusting the predetermined distance (D).

Furthermore, the surface tension coefficient of the gel 39 effects the forming curvature of the gel 39 as well. Therefore, the forming curvature of the gel 39 is controlled effectively by adjusting the predetermined distance (D) and using the gel 39 with different surface tension coefficients.

The predetermined region, the shape of the sectional side view of the groove, the shape of the top view of the groove, the manufacture of the groove and the predetermined distance (D) in each following embodiment of the present invention have the same spirit as the embodiments in FIG. 2A, FIG. 2B, FIG. 2C and FIG. 2D. Therefore, they are not described redundantly.

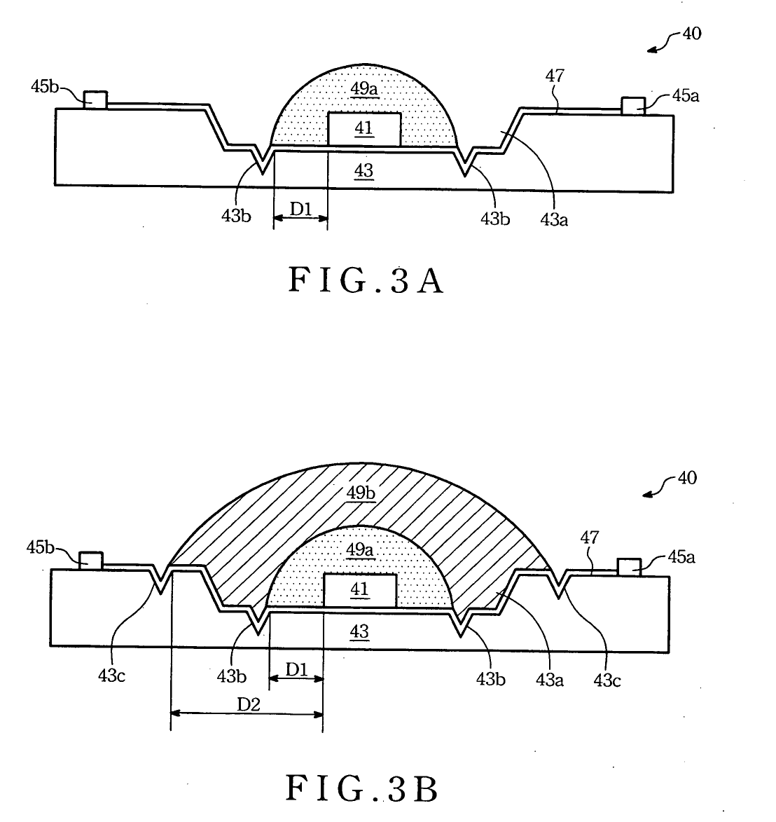

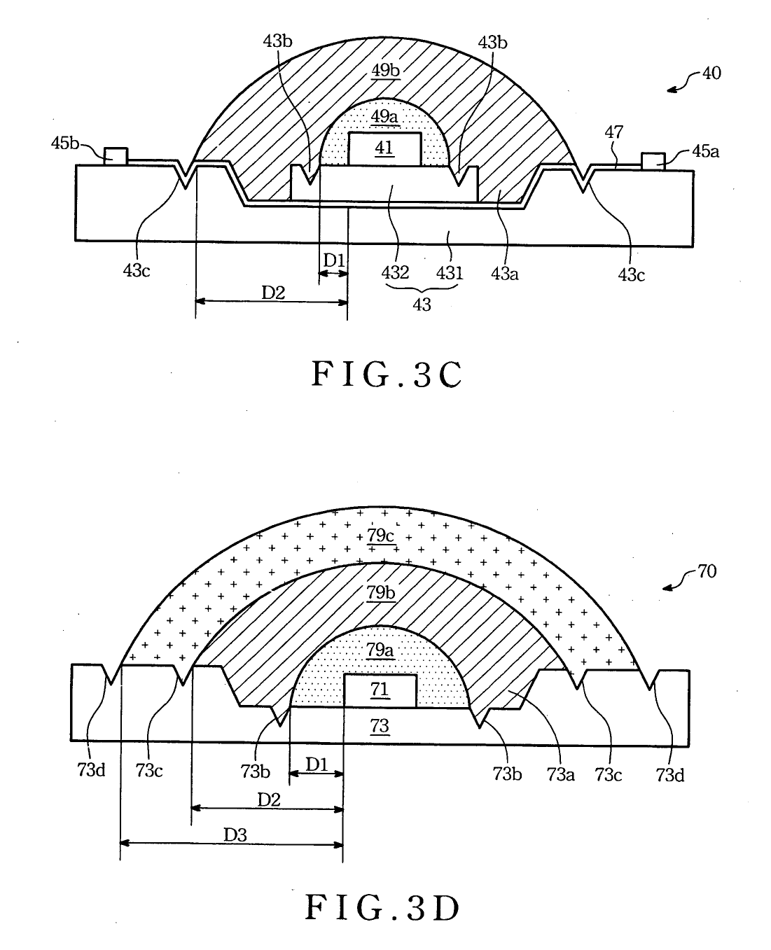

Please refer to FIG. 3A. FIG. 3A is a sectional side view of a light emitting diode package structure 40, according to the second embodiment of the present invention. The diode package structure 40 includes a light emitting diode 41, a substrate structure 43, electrodes 45a and 45b, an electrically conductive layer 47, and a gel 49. A surface of the substrate structure 43 has a concave 43a and at least one groove 43b. The groove 43b includes the first groove 43b. The first groove 43b is disposed in the concave 43a. The electrically conductive layer 47 is disposed on the surface of the substrate structure 43. The concave 43a is used for containing the light emitting diode 41. A first predetermined distance (D1) is between the first concave 43b and the light emitting diode 41. The first groove 43b is formed around the light emitting diode 41. The light emitting diode 41 is electrically connected to the electrodes 45a and 45b respectively by the electrically conductive layer 47. At least one gel 49 includes the first gel 49, for covering the light emitting diode 41, a portion of a surface of the concave 43a, and a portion of the electrically conductive layer 47 on the concave 43a. The gel 49 is limited to the surface tension in the first groove 43b and then is positioned in a predetermined region surrounded by the first groove 43b.

Please refer to FIG. 3B. FIG. 3B is a sectional side view of a light emitting diode package structure 40 according to the third embodiment of the present invention. In the third embodiment of the present invention, functions of most components are similar to or the same as those in the second embodiment in FIG. 3A. The difference between FIG. 3A and FIG. 3B is that the third embodiment further includes the second groove 43c and the second gel 49b. The second groove 43c is disposed on the surface of the substrate structure 43. And the second predetermined distance (D2) is between the light emitting diode 41 and the second groove 43c. The region covered by the electrically conductive layer 47 includes the surface of the second groove 43c. The second gel 49b covers the first gel 49a, the concave 43a, a portion of the electrically conductive layer 47 on the concave 43a, the second groove 43c, and a portion of the surface of the substrate structure 43. The second gel 49b is transparent, for protecting the first gel 49a and the light emitting diode 41 not to be invaded by outer particles or moisture.

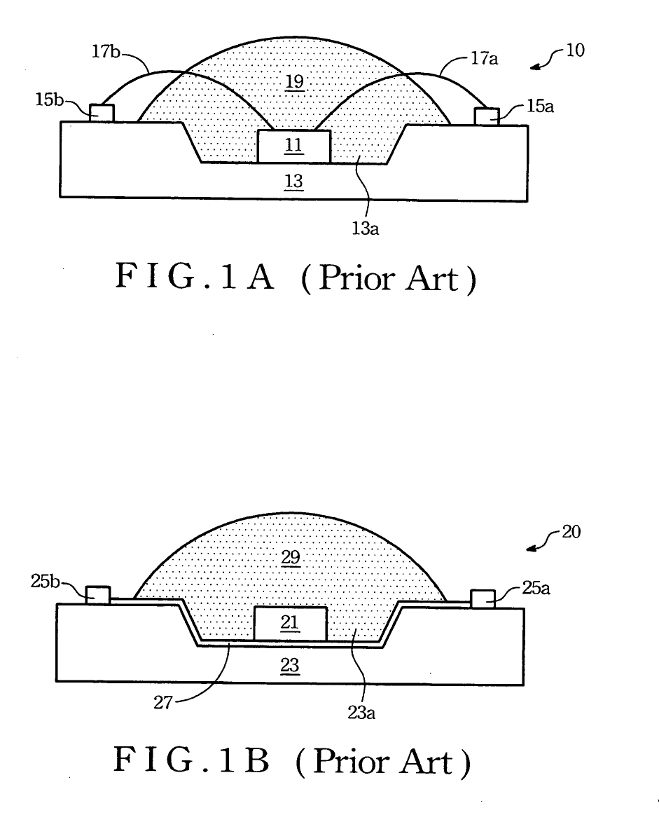

In summary, the advantages of the second embodiment and the third embodiment are as follow. The first gel 49a is dispensed precisely in the concave 43a through the first groove 43b. The region covered by the first gel 49a is obviously less than the region covered by the gel 29 (as shown in FIG. 1B). Therefore, the fluorescent materials are distributed in the first gel 49a more uniformly. As a result, when the light generated by the light emitting diode 41 passes through the first gel 49a, the light is more uniform. Also, the loss of light is decreased.

Furthermore, due to the design of the first groove 43b, the overflow problem in the process of gel dispensing is avoided. And the first gel 49a is positioned more precisely, further decreasing the occurrence of yellow circular light. Due to the design of the second groove 43c, the overflow problem in the process of gel dispensing is avoided. And the second gel 49b is positioned more precisely. Therefore, the light emitting diode package structure 40 decreases the loss of light and generates uniform light.

Please refer to FIG. 3C. FIG. 3C is a sectional side view of a light emitting diode package structure 40 according to the fourth embodiment of the present invention. In the present embodiment, functions of most components are similar to or the same as those in the embodiment in FIG. 3B. The difference between the FIG. 3B and FIG. 3C is that the substrate structure 43 in FIG. 3C includes a substrate 431 and a silicon carrier 432. The silicon carrier 432 is disposed in the concave 43a, for containing the light emitting diode 41. The silicon carrier 432 can be manufactured by a micro-electro-mechanical process. The first groove 43b is disposed on a surface of the silicon carrier 432. The first predetermined distance (D1) is between the first groove 43b and the light emitting diode 41. The region covered by the electrically conductive layer 47 does not include the first groove 43b as shown in FIG. 3B. The light emitting diode 41 is disposed on the silicon carrier 432. The silicon carrier 432 electrically connects the light emitting diode 41 with the electrically conductive layer 47. The light emitting diode package structure in the present embodiment further includes the first gel 49a and the second gel 49b. The first gel 49a covers the light emitting diode 41 and is dispensed within the first groove 43b. The second gel 49b covers the first gel 49a and a portion of the substrate structure 43. The second gel 49b is dispensed within the second groove 43c.

The first groove 43b is formed on the silicon carrier 432 of the substrate structure 43 by dry etching. Besides, the second groove 43c is formed on the substrate 431 of the substrate structure 43 by dry etching.

In addition to the advantages of the above embodiments, the present embodiment further includes the following advantages. In general, when the light emitting diode 41 is disposed in the concave 43a directly (as shown in FIG. 3B), the first gel 49a may be shifted due to the roughness of the surface of the concave 43a. Therefore, in the present embodiment, the first groove 43b formed on the substrate 44 improves the positioning of the gel 49a more effectively. Furthermore, because the surface of the concave 43a (please refer to FIG. 3B) is rough, the light emitting diode 41 (please refer to FIG. 3B) is damaged easily. Thus, the silicon carrier 432 disposed on the concave 43a provides the light emitting diode 41 with a smooth surface. As a result, the possibility of damaging the light emitting diode 41 is decreased.

Please refer to FIG. 3D. FIG. 3D is a sectional side view of a light emitting diode package structure 70 according to the fourth embodiment of the invention. The light emitting diode package structure 70 includes a light emitting diode 71, a substrate structure 73 and three layers of gels 79a, 79b and 79c. In the present embodiment, functions of most components are substantially the same as those in the above embodiments, and are described redundantly. The characteristic of the present embodiment is that there are several layers of gels. The materials of different layers of gels are chosen according to a rule of refractive index. Please refer to FIG. 3D. The light emitting diode package structure 70 has three layers of gels, including the first gel 79a, the second gel 79b and the third gel 79c from inside to outside. The refractive index of the first gel 79a is greater than that of the second gel 79b. The refractive index of the second gel 79b is greater than that of the third gel 79c. Through the specific arrangement of the gels, the light emitting diode package structure 70 has better light extraction efficiency from the light emitting diode 71. The specific arrangement according to refractive index can be referred to R.O.C. patent No. 94118456.

Based on the spirit of the present invention, please refer to FIG. 3D continuously. The first groove 73b, the second groove 73c and the third groove 73d are formed on the substrate structure 73 from center to periphery. The first predetermined distance (D1) is between the first groove 73b and the light emitting diode 71. The second predetermined distance (D2) is between the second groove 73c and the light emitting diode 71. The third predetermined distance (D3) is between the third groove 73d and the light emitting diode 71. The first groove 73b, the second groove 73c and the third groove 73d are formed around the light emitting diode 71. The process of gel dispensing in the present embodiment is more easily through the first groove 73b, the second groove 73c and the third groove 73d. The person who has ordinary skill in the field of the invention can understand that the process of gel dispensing in the present embodiment is more complicated than that of the above embodiments because the present embodiment uses several layers of gels (the reference numbers 79a, 79b and 79c in FIG. 3D). Several grooves are used for positioning several layers of gels in the proper positions. At the same time, the overflow problem of the gels is avoided. As a result, the speed of the manufacturing process can be increased, and the yield of the product is improved.

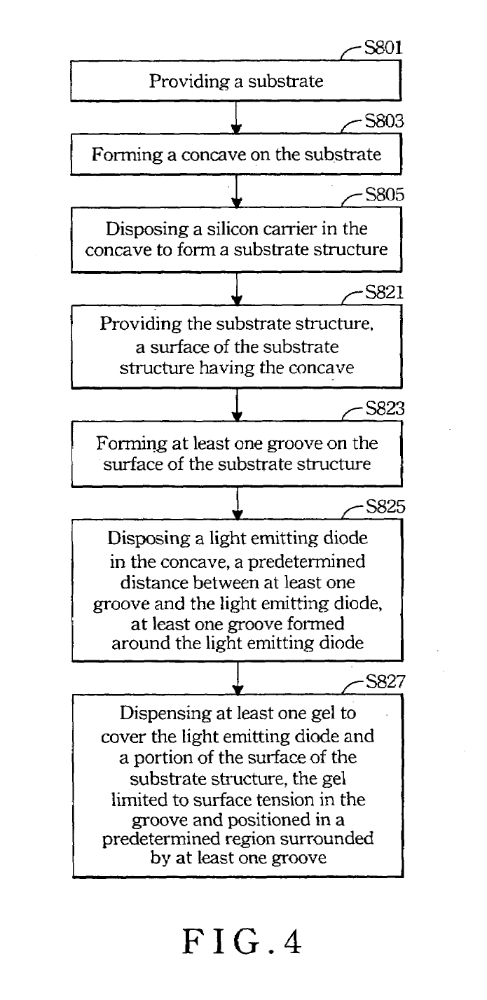

A manufacturing method of a light emitting diode package structure is provided by the present invention through summarizing all the embodiments of the invention. Please refer to FIG. 4. FIG. 4 is a flow chart of a manufacturing method of a light emitting diode package structure according to the present invention. The manufacturing method at least includes the following steps.

Step 821: a substrate structure is provided. A surface of the substrate structure has a concave.

Step 823: at least one groove is formed on the surface of the substrate structure.

Step 825: a light emitting diode is disposed in the concave. A predetermined distance (D) is between at least one groove and the light emitting diode. The groove is formed around the light emitting diode.

Step 827: in the process of del dispensing, at least one gel covers the light emitting diode and a portion of the surface of the substrate structure.

By the above steps, the gel is limited to the surface tension in the groove and is positioned in a predetermined region surrounded by the groove. Furthermore, in some embodiments of the present invention, the method further includes following steps before step 821.

Step 801: a substrate is provided. The substrate can be a metal substrate, such as an aluminum substrate.

Step 803: a concave is formed on the metal substrate. The concave can be formed by a cutter and a punch press.

Step 805: a silicon barrier is disposed on a surface of the metal substrate and positioned in the concave. The silicon barrier and the metal substrate compose the above-described substrate structure together. The light emitting diode is disposed on the silicon carrier, for easily assembling the substrate structure. Also, the silicon carrier provides a smoother surface which improves the positioning of the gel.

Based on the above description, the groove provided by the present invention not only avoids the overflow problem in the process of gel dispensing but also improves the positioning of the first gel. Furthermore, the occurrence of the yellow circular light is decreased, and the loss of light is reduced. The light provided by the light emitting diode is more uniform. Moreover, the gel with fluorescent materials is disposed precisely within a smaller region through the groove, so that the fluorescent materials are distributed in the gel more uniformly. Therefore, after the light generated by the light emitting diode passes through the gel, the light is more uniform. And the loss of light is decreased. Additionally, through a silicon carrier, the gel can be positioned more effectively on the substrate structure.

Moreover, several grooves can help to position several layers of gels precisely. At the same time, the overflow problem of the gel is avoided. As a result, the speed of the manufacturing process is increased, and the yield of the product is improved.

With the example and explanations above, the features and spirits of the invention are hopefully well described. Those skilled in the art will readily observe that numerous modifications and alterations of the device may be made while retaining the teaching of the invention. Accordingly, the above disclosure should be construed as limited only by the metes and bounds of the appended claims.

I claim:

1. A light emitting diode package structure, comprising:
a light emitting diode;
a substrate structure, a surface of the substrate structure having a concave and at least one groove, the concave used for containing the light emitting diode, a predetermined distance (D) between at least one groove and the light emitting diode, at least one groove formed around the light emitting diode; and
at least one gel covering the light emitting diode and a portion of the surface of the substrate structure, the gel limited to surface tension in the groove and positioned in a predetermined region surrounded by at least one groove.

2. The light emitting diode package structure of claim 1, wherein a sectional side view of the groove is a V-shape, a rectangle or a semicircle.

3. The light emitting diode package structure of claim 1, wherein a top view of the groove is a circle, a rectangle, a polygon, a discontinuous circle, a discontinuous rectangle or a discontinuous polygon.

4. The light emitting diode package structure of claim 1, wherein the groove is disposed outside the concave.

5. The light emitting diode package structure of claim 1, wherein the groove is disposed in the concave.

6. The light emitting diode package structure of claim 1, wherein substrate structure further comprises a substrate and a silicon carrier, the silicon carrier disposed in the concave, the light emitting diode disposed on the silicon carrier.

7. The light emitting diode package structure of claim 1, wherein at least one groove comprises a first groove, a first predetermined distance (D1) between the first groove and the light emitting diode, and at least one gel comprising a first gel.

8. The light emitting diode package structure of claim 7 further comprising a second gel covering the first gel, the surface of the substrate structure further having a second groove, a second predetermined distance (D2) between the second groove and the light emitting diode, the second groove formed around the light emitting diode.

9. The light emitting diode package structure of claim 8 further comprising a third gel covering the second gel, the surface of the substrate structure further having a third groove, a third predetermined distance (D3) between the third groove and the light emitting diode, the third groove formed around the light emitting diode.

10. The light emitting diode package structure of claim 9, wherein the refractive index of the first gel is greater than that of the second gel, the refractive index of the second gel greater than that of the third gel.

11. A manufacturing method of a light emitting diode package structure comprising:
providing a substrate structure, a surface of the substrate structure having a concave;
forming at least one groove on the surface of the substrate structure;
disposing a light emitting diode in the concave, a predetermined distance (D) between at least one groove and the light emitting diode, at least one groove formed around the light emitting diode; and
dispensing at least one gel to cover the light emitting diode and a portion of the surface of the substrate structure, the gel limited to surface tension in at least one groove and positioned in a predetermined region surrounded by at least one groove.

12. The manufacturing method of the light emitting diode package structure of claim 11 further comprising following steps before step of providing a substrate structure:
providing a substrate;
forming the concave on the substrate; and
disposing a silicon carrier in the concave to form the substrate structure;
wherein the light emitting diode is disposed on the silicon carrier.

13. The manufacturing method of the light emitting diode package structure of claim 12, wherein at least one groove is formed by dry etching in step of forming at least one groove on the surface of the substrate structure.

14. The manufacturing method of the light emitting diode package structure of claim 12, wherein at least one groove is formed by dry etching in step of forming at least one groove on the silicon carrier of the substrate structure.

15. The manufacturing method of the light emitting diode package structure of claim 12, wherein forming curvature of the gel is controlled by adjusting the predetermined distance (D) in step of dispensing the gel.
